(19) United States
(12) Patent Application Publication
(10) Pub. No.: US 2010/0295589 A1
(43) Pub. Date: Nov. 25, 2010

(54) MULTI-STAGE DIFFERENTIAL AMPLIFICATION CIRCUIT AND INPUT BUFFER FOR SEMICONDUCTOR DEVICE

(76) Inventor: Nam-Pyo Hong, Gyeonggi-do (KR)

Correspondence Address: IP & T GROUP LLP, 7700 Little River Turnpike, Suite 207, Annandale, VA, 22003, US

(21) Appl. No.: 12/494,485

(22) Filed: Jun. 30, 2009

(30) Foreign Application Priority Data
May 19, 2009 (KR) 10-2009-0043555

(51) Int. Cl. H03L 7/06; H03F 3/45

(52) U.S. Cl. 327/158; 330/253

(57) ABSTRACT

A multi-stage amplification circuit includes a common differential amplification unit configured to receive and detect differential input signals to generate a positive signal and a negative signal, a positive signal amplification unit configured to receive the positive signal and the negative signal through differential input terminals to generate a positive amplification signal, and a negative signal amplification unit configured to receive the positive signal and the negative signal through differential input terminals to generate a negative amplification signal.

### CROSS-REFERENCE TO RELATED APPLICATIONS

The present application claims priority of Korean Patent Application No. 10-2009-0043555, filed on May 19, 2009, the disclosure of which is incorporated herein by reference in its entirety.

### BACKGROUND OF THE INVENTION

The present invention relates to a semiconductor design technology, and more particularly, to a multi-stage differential amplification circuit and an input buffer for a semiconductor device.

A clock is a periodic pulse signal that toggles with a constant periodic cycle. In a semiconductor device, a clock signal is used to determine an enable timing of an internal circuit or an active timing of an internal signal in synchronization with a falling or rising edge. A clock may be inputted in a differential form: a positive clock signal and a negative signal. A toggling of a clock signal is also called a transition.

To improve an operating speed, a semiconductor device is operated by using high-frequency differential clock signals. External differential clock signals are buffered in a clock input buffer, and a semiconductor device uses the buffered clock signals.

FIG. 1 is a circuit diagram of a conventional clock input buffer for a semiconductor device.

Referring to FIG. 1, a conventional clock input buffer for a semiconductor device includes a first buffer 10A configured to generate a positive clock signal RCLK_OUT corresponding to external differential clock signals CLK and CLKB, and a second buffer 10B configured to generate a negative clock signal FCLK_OUT corresponding to the external differential clock signals CLK and CLKB. The positive clock signal RCLK_OUT and the negative clock signal FCLK_OUT are complementary to each other and have a 180-degree phase difference.

A detailed structure and operation of the conventional clock input buffer will be described.

The first buffer 10A includes a first signal input unit 11A and a first signal amplification unit 12A. The first signal input unit 11A receives the external differential clock signals CLK and CLKB to generate a positive signal REF and a negative signal REFB. The first signal amplification unit 12A receives the positive signal REF and the negative signal REFB through differential input terminals to output a positive clock signal RCLK_OUT.

The second buffer 10B includes a second signal input unit 11B and a second signal amplification unit 12B. The second signal input unit 11B receives the external differential clock signals CLK and CLKB to generate a positive signal REF and a negative signal REFB. The second signal amplification unit 12B receives the positive signal REF and the negative signal REFB through differential input terminals to output a negative clock signal FCLK_OUT.

The first signal input unit 11A and the second signal input unit 11B are a type of a differential signal detection circuit that detects the differential clock signals CLK and CLKB to output the positive signal REF and the negative signal REFB corresponding to the differential clock signals CLK and CLKB.

Each of the first signal input unit 11A and the second signal input unit 11B includes load units R1 and R2, differential input units MN1, MN2, MN3 and MN4, and a bias unit MN5. The load units R1 and R2 are connected between a power supply voltage terminal VDD and differential output terminals N0 and N1. The differential input units MN1, MN2, MN3 and MN4 are connected between the differential output terminals N0 and N1 and a common node N10 to receive the differential clock signals CLK and CLKB. The bias unit MN5 supplies a bias current to the common node N10 in response to an enable signal EN. The load units R1 and R2 are implemented with resistors. The differential clock signals CLK and CLKB inputted to the differential input units MN1, MN2, MN3 and MN4 of the first signal input unit 11A and the second signal input unit 11B have opposite phases. That is, when the first clock signal CLK is inputted to the first input unit MN1, MN3 and MP1 and the second clock signal CLKB having an opposite phase to the first clock CLK is inputted to the second input unit MN2, MN4 and MP2, the second clock signal CLKB is inputted to the first input unit MN1, MN2 and MP1 of the second signal input unit 11B and the first clock signal CLK is inputted to the second input unit MN2, MN4 and MP2. Therefore, the signals outputted from the differential output terminals N0 and N1 of the first signal input unit 11A have an opposite phase to the signals outputted from the differential output terminals N0 and N1 of the second signal input unit 11B.

Even when symmetry between the differential clock signals CLK and CLKB is disturbed, the first signal input unit 11A and the second signal input unit 11B can detect the differential clock signals CLK and CLKB relatively accurately and output the positive signal REF and the negative signal REFB corresponding to the differential clock signals CLK and CLKB.

Furthermore, the first signal amplification unit 12A outputs the positive clock signal RCLK_OUT corresponding to logic levels of the positive signal REF and the negative signal REFB outputted from the first signal input unit 11A, and the second signal amplification unit 12B outputs the negative clock signal FCLK_OUT corresponding to logic levels of the positive signal REF and the negative signal REFB outputted from the second signal input unit 11B.

In the conventional clock input buffer for the semiconductor device, as described above, the first buffer 10A generates the positive clock signal RCLK_OUT and the second buffer 10B generates the negative clock signal FCLK_OUT. Since the first buffer 10A and the second buffer 10B are arranged at different positions, symmetry between the positive clock signal RCLK_OUT and the negative clock signal FCLK_OUT may be disturbed. Moreover, since the circuit area of the clock input buffer is relatively large, its current consumption is relatively large.

### SUMMARY OF THE INVENTION

An embodiment of the present invention is directed to provide a multi-stage differential amplification circuit which reduces power consumption and circuit size by using a common differential amplification unit configured to detect differential input signals.

Another embodiment of the present invention is directed to provide an input buffer for a semiconductor device, which reduces power consumption and circuit size by using a common signal input unit configured to receive external differential input signals.

Another embodiment of the present invention is directed to provide a semiconductor device, which improves symmetry of clock signals of a delay locked loop (DLL).

In accordance with an aspect of the present invention, there is provided a multi-stage amplification circuit, including: a common differential amplification unit configured to receive and detect differential input signals to generate a positive signal and a negative signal; a positive signal amplification unit configured to receive the positive signal and the negative signal through differential input terminals to generate a positive amplification signal; and a negative signal amplification unit configured to receive the positive signal and the negative signal through differential input terminals to generate a negative amplification signal.

In accordance with another aspect of the present invention, there is provided an input buffer for a semiconductor device, the input buffer including: a common signal input unit configured to receive external differential input signals to generate a first positive signal and a first negative signal; a first signal amplification unit configured to receive the first positive signal and the first negative signal through differential input terminals to generate a second positive signal; and a second signal amplification unit configured to receive the first positive signal and the first negative signal through differential input terminals to generate a second negative signal.

In accordance with another aspect of the present invention, there is provided a multi-stage amplification circuit, including: a common differential amplification unit configured to receive a clock signal and an inverse signal of the clock signal and differentially generate a positive signal and a negative signal based on the received clock signals; a positive signal amplification unit configured to receive the positive signal and the negative signal through a first differential amplification unit to generate a positive amplification signal; and a negative signal amplification unit configured to receive the positive signal and the negative signal through a second differential amplification unit to generate a negative amplification signal having a substantially opposite phase from the positive amplification signal.

In accordance with another aspect of the present invention, there is provided a semiconductor device, including: a common signal input unit configured to receive external differential clock signals to generate a positive clock signal and a negative clock signal; a first signal amplification unit configured to receive the positive clock signal and the negative clock signal through differential input terminals to generate an internal positive clock signal; a second signal amplification unit configured to receive the positive clock signal and the negative clock signal through differential input terminals to generate an internal negative clock signal; and a delay locked loop configured to receive the internal positive clock signal and the internal negative clock signal to generate a delay locked loop clock signal.

In accordance with the embodiments of the present invention, one common circuit for detecting the differential input signals is provided, and the detection result of the common circuit is provided to the first and second signal amplification units at the same time. Hence, disruption of symmetry between the positive signal and the negative signal can be reduced. Moreover, the configuration of the common circuit can reduce the circuit size of the semiconductor device.

### BRIEF DESCRIPTION OF THE DRAWINGS

FIG. 1 is a circuit diagram of a conventional clock input buffer for a semiconductor device.

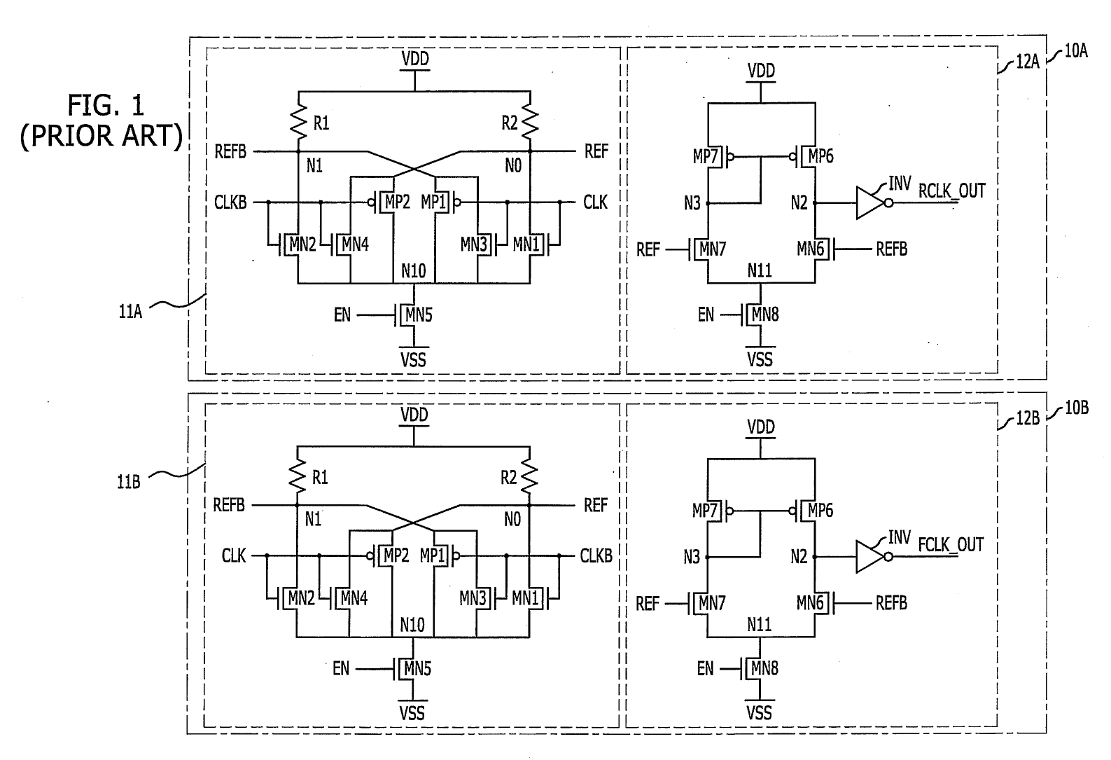

FIG. 2 is a circuit diagram of an input buffer for a semiconductor device in accordance with an embodiment of the present invention.

FIG. 3 is a diagram of a semiconductor device including an input buffer in accordance with an embodiment of the present invention.

### DESCRIPTION OF SPECIFIC EMBODIMENTS

Other objects and advantages of the present invention can be understood by the following description, and become apparent with reference to the embodiments of the present invention. In the drawings and detailed description, since the terms, numerals, and symbols used to indicate devices or blocks may be expressed by sub-units, it should be noted that the same terms, numerals, and symbols may not indicate the same devices in a whole circuit.

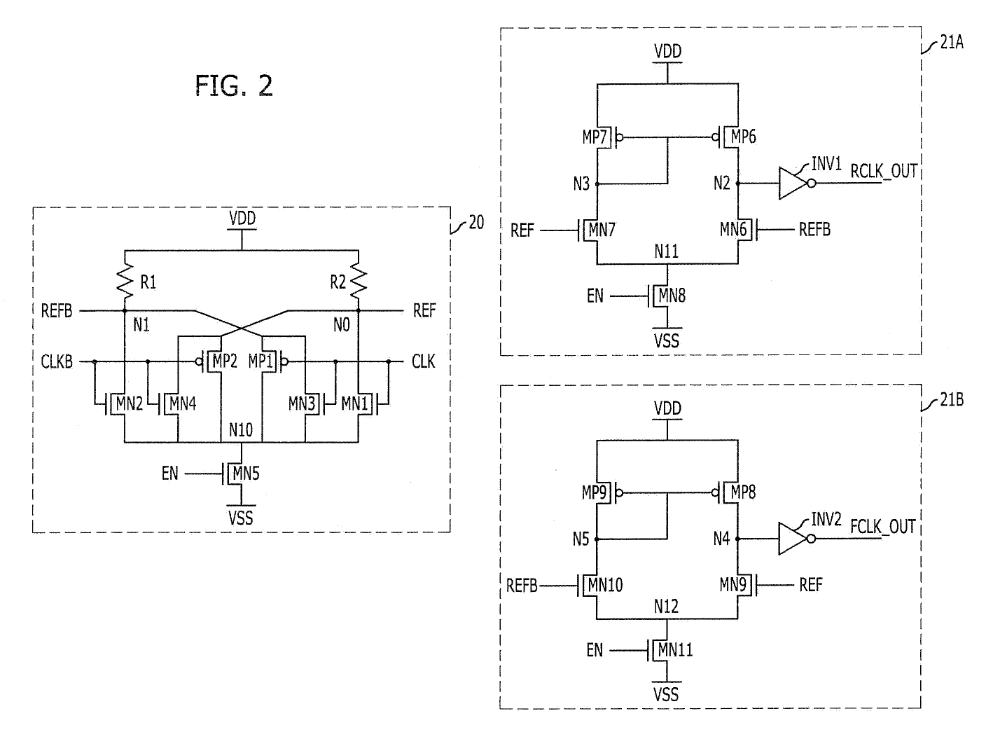

FIG. 2 is a circuit diagram of an input buffer for a semiconductor device in accordance with an embodiment of the present invention.

Referring to FIG. 2, an input buffer for a semiconductor device includes a common signal input unit 20, a first signal amplification unit 21A, and a second signal amplification unit 21B. The common signal input unit 20 receives external differential input signals CLK and CLKB to generate a first positive signal REF and a first negative signal REFB. The first signal amplification unit 21A receives the first positive signal REF and the first negative signal REFB through differential input terminals to generate a second positive signal RCLK_OUT. The second signal amplification unit 21B receives the first positive signal REF and the first negative signal REFB through differential input terminals to generate a second negative signal FCLK_OUT.

In this embodiment, the differential input signals CLK and CLKB are external differential clock signals, and the input buffer detects and buffers the external differential clock signals CLK and CLKB to output the second positive signal RCLK_OUT and the second negative signal FCLK_OUT, that is, a positive clock signal RCLK_OUT and a negative clock signal FCLK_OUT.

Any differential input signals can be buffered by the input buffer. That is, the input buffer in accordance with the current embodiment of the present invention can be used to buffer differential input signals, such as a command signal, a data strobe signal, a data signal, and an address signal.

A detailed description and operation of the input buffer in accordance with the embodiment of the present invention will be described below.

The common signal input unit 20 is a type of a differential signal detection circuit that detects the differential input signals CLK and CLKB to output the first positive signal REF and the first negative signal REFB corresponding to the differential input signals CLK and CLKB. The first positive signal REF and the first negative signal REFB have a 180-degree phase difference.

The common signal input unit 20 includes load units R1 and R2, differential input units MN1, MN2, MN3, MN4, MP1 and MP2, and a bias unit MN5. The load units R1 and R2 are connected between a power supply voltage terminal VDD and differential output terminals N0 and N1. The differential input units MN1, MN2, MN3, MN4, MP1 and MP2 are connected between the differential output terminals N0 and N1 and a common node N10 to receive the differential input signals CLK and CLKB. The bias unit MN5 supplies a bias current to the common node N10 in response to an enable signal EN. The load units R1 and R2 are implemented with resistors.

Even when symmetry between the differential input signals CLK and CLKB is disturbed, the common signal input unit 20 can detect the differential input signals CLK and CLKB accurately and output the first positive signal REF and the first negative signal REFB corresponding to the differential clock signals CLK and CLKB.

The first signal amplification unit 21A includes current mirroring units MP6 and MP7, differential input units MN6 and MN7, a bias unit MN8, and an inverter INV1. The current mirroring units MP6 and MP7 are connected between the power supply voltage terminal VDD and differential output terminals N2 and N3. The differential input units MN6 and MN7 are connected between the differential output terminals N2 and N3 and a common node N11 to receive the first positive signal REF and the first negative signal REFB. The bias unit MN8 supplies a bias current to the common node N11 in response to the enable signal EN. The inverter INV1 inverts an output signal of the first output terminal N2 to output the second positive signal RCLK_OUT.

The second signal amplification unit 21B includes current mirroring units MP8 and MP9, differential input units MN9 and MN10, a bias unit MN11, and an inverter INV2. The current mirroring units MP8 and MP9 are connected between the power supply voltage terminal VDD and differential output terminals N4 and N5. The differential input units MN9 and MN10 are connected between the differential output terminals N4 and N5 and a common node N12 to receive the first positive signal REF and the first negative signal REFB. The bias unit MN11 supplies a bias current to the common node N12 in response to the enable signal EN. The inverter INV2 inverts an output signal of the first output terminal N4 to output the second negative FCLK_OUT.

The first signal amplification unit 21A outputs the second positive signal RCLK_OUT corresponding to logic levels of the first positive signal REF and the first negative clock REFB, and the second signal amplification unit 21B outputs the second negative clock signal FCLK_OUT corresponding to logic levels of the first positive signal REF and the second negative signal REFB. That is, the first signal amplification unit 21A and the second signal amplification unit 21B output the positive clock signal RCLK_OUT and the negative clock signal FCLK_OUT, respectively, according to phases of the external differential input signals CLK and CLKB, that is, the differential clock signals.

The input buffer for the semiconductor device in accordance with the embodiment of the present invention is implemented as a multi-stage differential amplification circuit.

Specifically, the multi-stage differential amplification circuit includes a common differential amplification unit 20, a positive signal amplification unit 21A, and a negative signal amplification unit 21B. The common differential amplification unit 20 detects differential input signals to generate a positive signal and a negative signal. The positive signal amplification unit 21A receives the positive signal and the negative signal through differential input terminals to generate a positive amplification signal. The negative signal amplification unit 21B receives the positive signal and the negative signal through differential input terminals to generate a negative amplification signal.

The multi-stage differential amplification circuit detects and amplifies the input signals through two amplification stages.

At the first amplification stage for generating the positive amplification signal, the common differential amplification unit 20 detects the differential input signals accurately to generate the positive signal and the negative signal. At the second amplification stage, the positive signal amplification unit 21A finally outputs the positive amplification signal corresponding to logic levels of the positive signal and the negative signal.

At the first amplification stage for generating the negative amplification signal, the common differential amplification unit 20 detects the differential input signals accurately to generate the positive signal and the negative signal. At the second amplification stage, the negative signal amplification unit 21B finally outputs the negative amplification signal corresponding to logic levels of the positive signal and the negative signal.

Even when symmetry between the differential input signals is mismatched, the first amplification stage for generating the positive amplification signal and the negative amplification signal can detect the signals accurately. Also, the second amplification stage substantially amplifies the detected signals. The multi-stage differential amplification circuit may be applied to an input buffer for buffering external input signal, and may also be used to amplify internal differential signals.

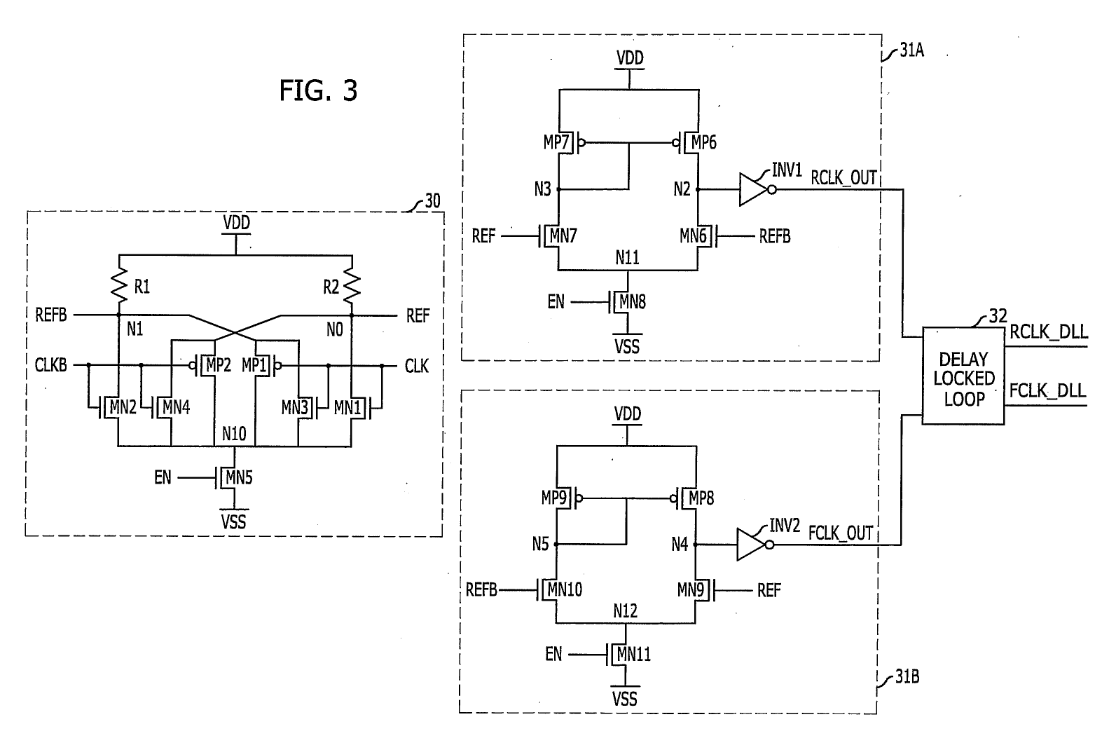

FIG. 3 is a diagram of a semiconductor device including an input buffer in accordance with an embodiment of the present invention.

Referring to FIG. 3, a semiconductor device includes a common signal input unit 30, a first signal amplification unit 31A, a second signal amplification unit 31B, and a delay locked loop (DLL) 32. The common signal input unit 30 receives external differential clock signals CLK and CLKB to generate a positive clock signal REF and a negative clock signal REFB. The first signal amplification unit 31A receives the positive clock signal REF and the negative clock signal REFB through differential input terminals to generate an internal positive clock signal RCLK_OUT. The second signal amplification unit 31B receives the positive clock signal REF and the negative clock signal REFB through differential input terminals to generate an internal negative clock signal FCLK_OUT. The DLL 32 receives the internal positive clock signal RCLK_OUT and the internal negative clock signal FCLK_OUT to generate a delay locked loop clock signals RCLK_DLL and FCLK_DLL.

In this embodiment, the DLL 32 of the semiconductor device receives the internal positive clock signal RCLK_OUT and the internal negative clock signal FCLK_OUT and generates the DLL clock signals RCLK_DLL and FCLK_DLL. Since the symmetry of the internal positive clock signal RCLK_OUT and the internal negative clock signal FCLK_OUT is improved through the common signal input unit 30, the first signal amplification unit 31A and the second signal amplification unit 31B, the symmetry of the DLL clock signals RCLK_DLL and FCLK_DLL is improved, of course. Because the semiconductor device receives the external differential clock signals CLK and CLKB through the common signal input unit 30, the size and power consumption of the semiconductor device may reduce.

In accordance with the embodiments of the present invention, the size and power consumption of the multi-stage differential amplification circuit and the input buffer can be reduced, and the differential signals having a better symmetry between the positive signal and the negative signal can be generated.

Furthermore, since DLL clock signals are generated by using the differential clock signals having a better symmetry between the positive signal and the negative signal, the symmetry of the DLL clock signals may be improved.

While the present invention has been described with respect to the specific embodiments, it will be apparent to those skilled in the art that various changes and modifications may be made without departing from the spirit and scope of the invention as defined in the following claims.

For example, although not directly related to the technical spirit of the present invention, embodiments including additional structures may be exemplified for further detailed description. Furthermore, the active high or active low structure representing the activation states of signals or circuits may be changed according to embodiments. Moreover, the configurations of the transistors may also be changed in order to implement the same functions. That is, the PMOS transistor and the NMOS transistor may be exchanged with each other and, if necessary, a variety of transistors may be used herein. Moreover, modifications can be made in the logic gate configurations in order to implement the same functions. That is, NAND units and NOR units may be implemented with various combinations of NAND gates, NOR gates, and inverters. Numerous modifications can be made in the circuit configuration and is within the skill of ordinary artisan in the art. Therefore, their enumeration is omitted herein.

What is claimed is:

1. A multi-stage amplification circuit, comprising:
a common differential amplification unit configured to receive and detect differential input signals to generate a positive signal and a negative signal;
a positive signal amplification unit configured to receive the positive signal and the negative signal through differential input terminals to generate a positive amplification signal; and
a negative signal amplification unit configured to receive the positive signal and the negative signal through differential input terminals to generate a negative amplification signal.

2. An input buffer for a semiconductor device, the input buffer comprising:
a common signal input unit configured to receive external differential input signals to generate a first positive signal and a first negative signal;
a first signal amplification unit configured to receive the first positive signal and the first negative signal through differential input terminals to generate a second positive signal; and
a second signal amplification unit configured to receive the first positive signal and the first negative signal through differential input terminals to generate a second negative signal.

3. The input buffer of claim 2, wherein the differential input signals comprise differential clock signals.

4. The input buffer of claim 2, wherein the differential input signals comprise differential command signals.

5. The input buffer of claim 2, wherein the differential input signals comprise differential data strobe signals.

6. The input buffer of claim 2, wherein the differential input signals comprise differential data signals.

7. The input buffer of claim 2, wherein the differential input signals comprise differential address signals.

8. The input buffer of claim 2, wherein the common signal input unit comprises a differential signal detection unit configured to detect the differential input signals to output the first positive signal and the first negative signal based on the detected differential input signals.

9. The input buffer of claim 8, wherein the differential signal detection unit comprises:
a load unit connected between a power supply voltage terminal and a differential output terminal;
a differential input unit connected between the differential output terminal and a common node to receive the differential input signals; and
a bias unit configured to supply a bias current to the common node in response to an enable signal.

10. The input buffer of claim 9, wherein the load unit comprises a plurality of resistors.

11. The input buffer of claim 2, wherein the first signal amplification unit comprises:
a current mirroring unit connected between a power supply voltage terminal and a differential output terminal;
a differential input unit connected between the differential output terminal and a common node to receive the first positive signal and the first negative signal;
a bias unit configured to supply a bias current to the common node in response to an enable signal; and
an inverter configured to invert an output signal of a first output terminal of the differential output terminals to output the second positive signal.

12. The input buffer of claim 2, wherein the second signal amplification unit comprises:
a current mirroring unit connected between a power supply voltage terminal and a differential output terminal;
a differential input unit connected between the differential output terminal and a common node to receive the first positive signal and the first negative signal;
a bias unit configured to supply a bias current to the common node in response to an enable signal; and
an inverter configured to invert an output signal of a first output terminal of the differential output terminals to output the second negative signal.

13. A multi-stage amplification circuit, comprising:
a common differential amplification unit configured to receive a clock signal and an inverse signal of the clock signal and differentially generate a positive signal and a negative signal based on the received clock signals;
a positive signal amplification unit configured to receive the positive signal and the negative signal through a first differential amplification unit to generate a positive amplification signal; and
a negative signal amplification unit configured to receive the positive signal and the negative signal through a second differential amplification unit to generate a negative amplification signal having a substantially opposite phase from the positive amplification signal.

14. The multi-stage amplification circuit of claim 13, wherein the common differential amplification unit comprises:
a load unit connected between a power supply voltage terminal and a differential output terminal;
a differential input unit connected between the differential output terminal and a common node to receive the clock signals; and
a bias unit configured to supply a bias current to the common node in response to an enable signal.

15. The multi-stage amplification circuit of claim 13, wherein the positive signal amplification unit comprises:
a current mirroring unit connected between a power supply voltage terminal and a couple of differential output terminals;
a differential input unit connected between the differential output terminals and a common node to receive the positive signal and the negative signal;
a bias unit configured to supply a bias current to the common node in response to an enable signal; and
an inverter configured to invert an output signal of a first output terminal of the differential output terminals to output the positive amplification signal.

16. A semiconductor device, comprising:
a common signal input unit configured to receive external differential clock signals to generate a positive clock signal and a negative clock signal;
a first signal amplification unit configured to receive the positive clock signal and the negative clock signal through differential input terminals to generate an internal positive clock signal;
a second signal amplification unit configured to receive the positive clock signal and the negative clock signal through differential input terminals to generate an internal negative clock signal; and
a delay locked loop configured to receive the internal positive clock signal and the internal negative clock signal to generate a delay locked loop clock signal.
